(19) United States
(12) Patent Application Publication
(10) Pub. No.: US 2026/0164884 A1
(43) Pub. Date: Jun. 11, 2026

(54) LIGHT EMITTING DEVICE

(71) Applicant: InnoLux Corporation, Miao-LiCounty (TW)

(72) Inventors: Hsiao-Lang LIN, Miao-LiCounty (TW); Tsung-Han TSAI, Miao-LiCounty (TW)

(21) Appl. No.: 19/385,170

(22) Filed: Nov. 11, 2025

(30) Foreign Application Priority Data
Dec. 10, 2024 (CN) 202411804419.2

(51) Int. Cl. H10H 29/39; H10H 29/41; H10H 29/49; H10H 29/85; H10H 29/851; H10H 29/856

(52) U.S. Cl. CPC H10H 29/39; H10H 29/41; H10H 29/49; H10H 29/8515; H10H 29/8517; H10H 29/856

(57) ABSTRACT

A light emitting device includes a substrate, a first transistor, a first light emitting unit and a color conversion structure. The first transistor and the first light emitting unit are disposed on the substrate. The color conversion structure is disposed between the first transistor and the first light emitting unit, and has a first portion overlapped with the first light emitting unit and a second portion adjacent to the first portion. A light of the first light emitting unit passes through the first portion and the substrate, and the first light emitting unit is electrically connected to the first transistor through the second portion.

### BACKGROUND OF THE DISCLOSURE

### 1. Field of the Disclosure

The present disclosure relates to a light emitting device, and more particularly to a light emitting device having a low-resistance electrical connection path existing between electronic components.

### 2. Description of the Prior Art

As the evolution and development of electronic devices, the electronic devices have become an indispensable item. For instance, a light emitting device which is a kind of the electronic device can be capable of producing light to be widely used. Based on requirement(s), the light emitting device may optionally have a displaying function to be a display device, so as to transmit information and/or display an image.

In order to improve the performance of electronic components in the electronic device (such as light emitting units in the light emitting device), the electrical connection paths connected to the electronic components in the electronic device need to be appropriately designed according to the structure of the electronic device for reducing the resistances of the electrical connection paths. Therefore, the performance of the electronic component would be improved through the design of the electrical connection path connected to the electronic component. Even, some components in the electronic device may be omitted to save the manufacturing cost of the electronic device if the design of the electrical connection path is suitable.

### SUMMARY OF THE DISCLOSURE

According to an embodiment, the present disclosure provides a light emitting device including a substrate, a first transistor, a first light emitting unit and a color conversion structure. The first transistor and the first light emitting unit are disposed on the substrate. The color conversion structure is disposed between the first transistor and the first light emitting unit, and has a first portion overlapped with the first light emitting unit and a second portion adjacent to the first portion. A light of the first light emitting unit passes through the first portion and the substrate, and the first light emitting unit is electrically connected to the first transistor through the second portion.

### BRIEF DESCRIPTION OF THE DRAWINGS

FIG. 1 is a schematic diagram showing a top view of a light emitting device according to a first embodiment of the present disclosure.

FIG. 2 is a schematic diagram showing a cross-sectional view of the light emitting device according to the first embodiment of the present disclosure.

FIG. 3 is a schematic diagram showing a top view of a light emitting device according to a second embodiment of the present disclosure.

FIG. 4 is a schematic diagram showing a cross-sectional view of a structure taken along a cross-sectional line A-A′ in FIG. 3.

FIG. 5 is a schematic diagram showing a cross-sectional view of a light emitting device according to a third embodiment of the present disclosure.

FIG. 6 is a schematic diagram showing a cross-sectional view of a light emitting device according to a fourth embodiment of the present disclosure.

FIG. 7 is a schematic diagram showing a cross-sectional view of a light emitting device according to a fifth embodiment of the present disclosure.

FIG. 8 is a schematic diagram showing a cross-sectional view of a light emitting device according to a sixth embodiment of the present disclosure.

FIG. 9 is a schematic diagram showing a cross-sectional view of a light emitting device according to a seventh embodiment of the present disclosure.

FIG. 10 is a schematic diagram showing a cross-sectional view of a light emitting device according to an eighth embodiment of the present disclosure.

FIG. 11 is a schematic diagram showing a cross-sectional view of a light emitting device according to a ninth embodiment of the present disclosure.

FIG. 12 is a schematic diagram showing a cross-sectional view of a light emitting device according to a tenth embodiment of the present disclosure.

FIG. 13 is a schematic diagram showing a cross-sectional view of a light emitting device according to an eleventh embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components with the same function but different names.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, regions, steps, operations and/or components would be pointed to existence, but not limited to the existence of one or a plurality of the corresponding features, regions, steps, operations and/or components.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each region, and/or each structure may be reduced or enlarged.

When the corresponding component such as layer or region is referred to “on another component”, it may be directly on this another component, or other component(s) may exist between them. On the other hand, when the component is referred to “directly on another component (or the variant thereof)”, any component does not exist between them. Furthermore, when the corresponding component is referred to “on another component”, the corresponding component and the another component have a disposition relationship along a top-view/vertical direction, the corresponding component may be below or above the another component, and the disposition relationship along the top-view/vertical direction are determined by an orientation of the device.

It will be understood that when a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the description and following claims, the term “horizontal direction” generally means a direction parallel to a horizontal plane, the term “horizontal plane” generally means a surface parallel to a direction X and direction Y in the drawings, the term “vertical direction” generally means a direction parallel to a direction Z and perpendicular to the horizontal direction in the drawings, and the direction X, the direction Y and the direction Z are perpendicular to each other. In the description and following claims, the term “top view” generally means a viewing result viewing along the vertical direction. In the description and following claims, the term “cross-sectional view” generally means a structure cut along the vertical direction is viewed along the horizontal direction.

In the description and following claims, it should be noted that the term “overlap” means that two elements overlap along the direction Z, and the term “overlap” can be “partially overlap” or “completely overlap” in unspecified circumstances.

In the description and following claims, the term “width” means a maximum size of a component along the horizontal direction in cross-sectional view, and the term “depth” means a maximum size of a component along the vertical direction in cross-sectional view (e.g., a distance between a bottom and a top of this component).

In the description and following claims, in unspecified circumstances, conductive material(s) may include metal, transparent conductive material (e.g., indium tin oxide (ITO), indium zinc oxide (IZO), etc.), other suitable conductive material(s) or a combination thereof, and a structure containing the conductive material(s) may be a single-layer structure or a multi-layer structure. In the description and following claims, in unspecified circumstances, insulating material(s) may include silicon oxide (SiOₓ), silicon nitride (SiN_{y}), silicon oxynitride (SiON_{y}), organic insulating material (e.g., photosensitive resin), other suitable insulating material(s) or a combination thereof, and a structure containing the insulating material(s) may be a single-layer structure or a multi-layer structure.

The terms “about”, “approximately”, “substantially”, “equal”, or “same” generally mean within ±20% of a given value or range, or mean within ±10%, ±5%, ±3%, ±2%, ±1%, or ±0.5% of a given value or range.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, in the following description, a first constituent element may be a second constituent element in a claim.

It should be noted that the technical features in different embodiments described in the following can be replaced, recombined, or mixed with one another to constitute another embodiment without departing from the spirit of the present disclosure.

In the present disclosure, the electronic device may include a display device, a lighting device, an antenna device, a sensing device, a tiled device or a combination thereof, but not limited thereto. The light emitting device may be capable of generating light, so as to serve as a light source (e.g., a backlight module), a display device capable of displaying or other suitable light emitting device. The display device may be a non-self-luminous type display device or a self-luminous type display device based on requirement(s), and the display device may be a color display device or a monochrome display device based on requirement(s). The antenna device may be a liquid-crystal-type antenna device or a non-liquid-crystal-type antenna device, the sensing device may be a device for sensing capacitance, light, thermal or ultrasonic, and the tiled device may be a tiled display device or a tiled antenna device, but not limited thereto. Electronic components in the electronic device may include passive component(s) and active component(s), such as capacitor(s), resistor(s), inductor(s), diode(s), transistor(s) and/or integrated circuit(s), but not limited thereto. The diode may include a light emitting diode (LED) or a photodiode. The light emitting diode may include an organic light emitting diode (OLED), a mini LED, a micro LED or a quantum dot LED, but not limited thereto. The transistor may include a top gate thin film transistor, a bottom gate thin film transistor or a dual gate thin film transistor, but not limited thereto. The electronic device may include fluorescence material, phosphorescence material, quantum dot (QD) material or other suitable material based on requirement(s), but not limited thereto. The electronic device may have a peripheral system (such as a driving system, a control system, a light system, etc.) for supporting the device(s) and the component(s) in the electronic device.

For example, the light emitting device having the displaying function and capable of generating color light (i.e., a color display device) is described in the following.

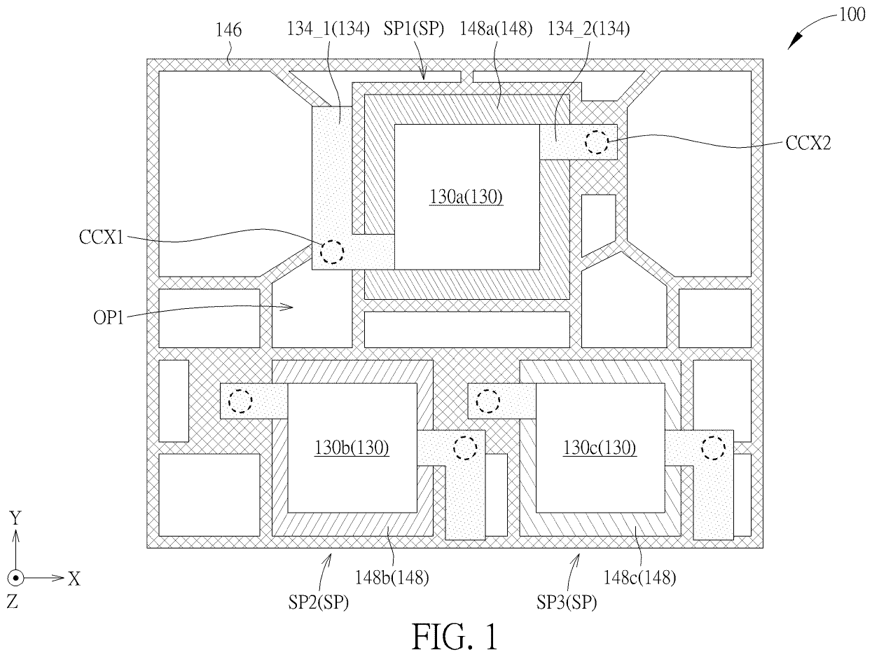

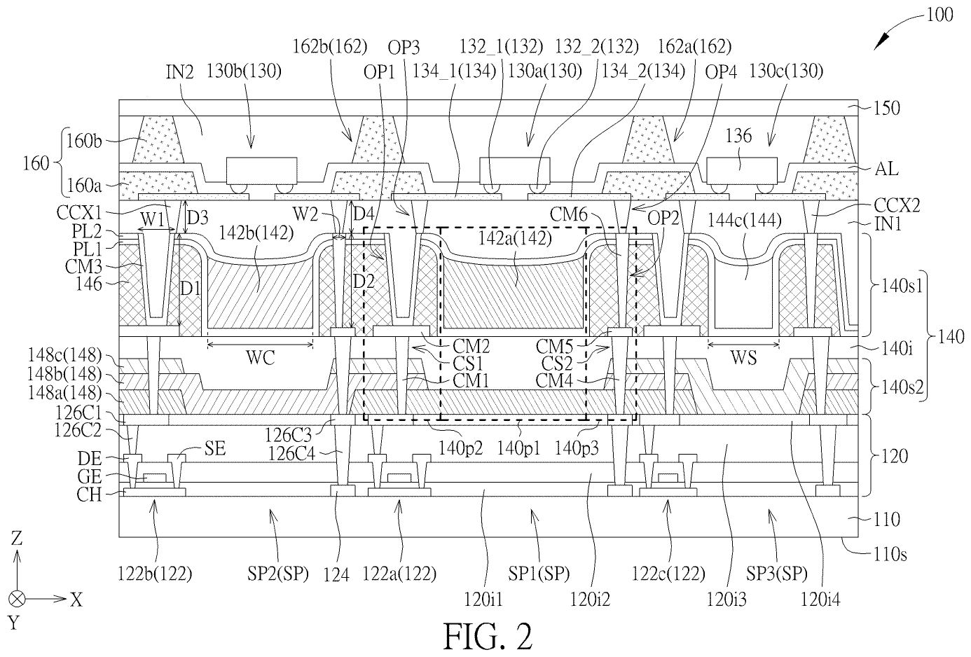

Referring to FIG. 1 and FIG. 2, FIG. 1 is a schematic diagram showing a top view of a light emitting device according to a first embodiment of the present disclosure, and FIG. 2 is a schematic diagram showing a cross-sectional view of the light emitting device according to the first embodiment of the present disclosure, wherein FIG. 2 simultaneously shows the cross-sectional structures of the different positions in FIG. 1, such that the cross-sectional view shown in FIG. 2 would be obtained by taking multiple cross-sections of the structure shown in FIG. 1. As shown in FIG. 1 and FIG. 2, the light emitting device 100 may include a substrate 110. The substrate may be rigid or flexible, and the substrate 110 may include suitable material based on its type. For instance, the substrate 110 may include glass, quartz, ceramic, sapphire, polymer (e.g., polyimide (PI), polyethylene terephthalate (PET), etc.), silicon, other elastic materials, other flexible materials, other suitable materials or a combination thereof. Note that a normal direction of the substrate 110 may be parallel to the direction Z.

Optionally, the light emitting device 100 may include an opposite substrate (not shown in figures) opposite to the substrate 110. The opposite substrate may be rigid or flexible, and the opposite substrate may include suitable material based on its type. For instance, the opposite substrate may include glass, quartz, ceramic, sapphire, polymer (e.g., PI, PET, etc.), silicon, other elastic materials, other flexible materials, other suitable materials or a combination thereof.

As shown in FIG. 1 and FIG. 2, the light emitting device 100 may include a plurality of pixels, and each pixel may include at least one sub-pixel SP, wherein the pixel is a unit configured to display an image, the number and color(s) of the sub-pixel(s) SP in each pixel may be adjusted based on requirement(s), and the arrangement of the sub-pixels SP and the arrangement of the pixels may be designed based on requirement(s). In some embodiments (as shown in FIG. 1 and FIG. 2), if the light emitting device 100 generates the color light to be a color display device, one pixel may include a plurality of sub-pixels SP1, SP2 and SP3 corresponding to different colors for instance (e.g., the sub-pixels SP may be a green sub-pixel, a red sub-pixel and a blue sub-pixel respectively), but not limited thereto. In another embodiment (not shown in figures), the light emitting device 100 may generate the light with single color to be a monochrome display device, and one pixel may include one sub-pixel SP, but not limited thereto.

In the present disclosure, the pixel and the sub-pixel SP may be disposed on the substrate 110, and include the electronic component(s) and structure(s) disposed on the substrate 110. In some embodiments, the pixel and the sub-pixel SP may be disposed between the substrate 110 and the opposite substrate, and include the electronic component(s) and structure(s) disposed between the substrate 110 and the opposite substrate.

As shown in FIG. 2, the light emitting device 100 may include a circuit component layer 120 disposed on the substrate 110, wherein the circuit component layer 120 may include corresponding electronic components and corresponding structures according to the functions included in the light emitting device 100. For example, the circuit component layer 120 may include a transistor 122 (e.g., a thin film transistor (TFT)), a passive component (not shown in figures, for instance, a capacitor), a conductive trace (e.g., a signal line 124 shown in FIG. 2, a scan line not shown in figures, a data line not shown in figures, etc.), a driving circuit (not shown in figures, for instance, a gate drive circuit), other suitable component(s) or a combination thereof. In the present disclosure, one sub-pixel SP may include at least one transistor 122 and optionally include other electronic component(s), wherein the number of the transistor(s) 122 included in one sub-pixel SP may be designed based on requirement(s). For example, in FIG. 2, the sub-pixel SP1 may include a first transistor 122a, the sub-pixel SP2 may include a second transistor 122b, and the sub-pixel SP3 may include a third transistor 122c, but not limited thereto. For instance, the transistor 122 may include a high mobility component, an oxide TFT, low-temperature polycrystalline silicon (LTPS), single gate, dual gate, single channel, dual channel, auxiliary gate high mobility oxide (HMO) semiconductor, multi-channel or a combination thereof, but not limited thereto. For instance, the light emitting device 100 may use a micro integrated circuit (micro IC) for driving (e.g., the driving circuit may be a micro IC driver), but not limited thereto. The driving circuit may use a pulse-amplitude modulation (PAM), a pulse-width modulation (PWM) or a combination thereof, but not limited thereto.

In the present disclosure, the conductive trace may be designed based on requirement(s). For instance, the signal line 124 may be configured to transmit a reference signal (e.g., a common signal), but not limited thereto. For instance, the scan line may be electrically connected to the transistor 122 and be configured to transmit a switching signal, wherein a switching status of the transistor 122 electrically connected to the scan line may be controlled by the switching signal, but not limited thereto. For instance, the data line may be electrically connected to the transistor 122 and be configured to transmit a data signal, wherein a light intensity of the light generated from the sub-pixel SP may be corresponding to the data signal transmitted to this sub-pixel SP, but not limited thereto. In addition, the arrangements of the conductive traces (e.g., extending directions of the conductive traces) may be designed based on their types. For instance, the extending direction of the scan line may be different from the extending direction of the data line, but not limited thereto.

The circuit component layer 120 may include at least one conductive layer, at least one insulating layer, at least one semiconductor layer or a combination thereof, so as to form the electronic components and the structures in the circuit component layer 120. The conductive layer in the circuit component layer 120 may include the conductive material(s), the insulating layer in the circuit component layer 120 may include the insulating material(s), and the material of the semiconductor layer in the circuit component layer 120 may include poly-silicon, amorphous silicon, metal-oxide semiconductor, other suitable semiconductor material(s) or a combination thereof, but not limited thereto.

For instance, in the circuit component layer 120, the transistor 122 may be a top gate thin film transistor, and the transistor 122 may include a gate electrode GE, a source electrode SE, a drain electrode DE and a channel layer CH, wherein the gate electrode GE may be included in a conductive layer, the source electrode SE and the drain electrode DE may be included in another conductive layer, and the channel layer CH may be included in a semiconductor layer, but not limited thereto. Moreover, in the circuit component layer 120, the conductive trace may be included in the suitable conductive layer. For instance, the signal line 124, the scan line, and the data line may be included in different conductive layers respectively, but not limited thereto.

For instance, in the circuit component layer 120, an insulating layer 120i1 is disposed between the channel layer CH and the gate electrode GE, an insulating layer 12012 is disposed on the gate electrode GE and passed through the source electrode SE and the drain electrode DE, an insulating layer 12013 is disposed on the source electrode SE and the drain electrode DE, and an insulating layer 12014 is disposed on the insulating layer 12013, so as to separate the conductive structures in the circuit component layer 120.

As shown in FIG. 1 and FIG. 2, the light emitting device 100 may include a plurality of light emitting units 130 disposed on the substrate 110 and configured to generate light passes through the substrate 110 (i.e., a light-emitting surface of the light emitting device 100 of the present disclosure is a bottom surface 110s of the substrate 110), wherein the light emitting unit 130 is disposed on the circuit component layer 120 and electrically connected to the electronic component(s) of the circuit component layer 120. In the present disclosure, a color of the light generated by the light emitting unit 130 may be designed based on requirement(s). For instance, the light of the light emitting unit 130 may be blue light, white light or other light with suitable color, or the light of the light emitting unit 130 have suitable light emission spectrum based on requirement(s). In the present disclosure, one sub-pixel SP may include at least one light emitting unit 130, a number of the light emitting unit(s) 130 included in one sub-pixel SP may be designed based on requirement(s). For instance, the light emitting unit(s) 130 included in one sub-pixel SP may be connected in parallel, in series, or in a combination thereof, but not limited thereto. For instance, in FIG. 1 and FIG. 2, the sub-pixel SP1 may include one first light emitting unit 130a, the sub-pixel SP2 may include one second light emitting unit 130b, and the sub-pixel SP3 may include one third light emitting unit 130c, but not limited thereto. In one sub-pixel SP, the electronic components in the circuit component layer 120 and the light emitting unit 130 are electrically connected to each other to form a sub-pixel circuit, the light intensity of the light of the light emitting unit 130 may be corresponding to the data signal transmitted to this sub-pixel SP. Or, the electrical connection between the light emitting unit 130 and the circuit component layer 120 may be driven by a lapping circuit (not shown in figures, for instance, after transferring the light emitting unit 130, the circuit component layer 120 lapping on the light emitting unit 130 is formed).

In the present disclosure, the light emitting unit 130 may be any suitable light emitting component. For instance, the light emitting unit 130 may be a LED, the LED may include an OLED, a mini LED, a micro LED or a quantum dot LED, and the positions of semiconductor layer(s), light emitting layer(s) and electrode(s) in the LED may be correspondingly designed based on the type of the LED (e.g., a vertical LED, a lateral LED, a flip chip LED, a Nano-rod LED, a quantum Nano-emitting diode (QNED)), but not limited thereto. For instance, in FIG. 2, the light emitting unit 130 may be a lateral micro LED, such that the light emitting unit 130 has the electrodes (e.g., two electrodes) on the same side, but not limited thereto. Note that, the electrode of the light emitting unit 130 may be a pin 132 of the light emitting unit 130 and/or a pad electrically connected to (e.g., bonded with) the pin 132, and the electrodes are configured to receive the same signal or different signals (e.g., the data signal, the reference signal, etc.). For instance, the bonding method may be a eutectic bonding method, a bonding method through an anisotropic conductive film (ACF) or a combination thereof, but not limited thereto.

Moreover, the pad may belong to a portion of a conductive part 134 in the light emitting device 100 (i.e., the pad may include the conductive material(s)), wherein the conductive part 134 is a structure in a conductive layer. Furthermore, the pin 132 of the light emitting unit 130 may be electrically connected to the pad by any suitable manner. For instance, in FIG. 2, the pin 132 of the light emitting unit 130 may be bonded on the pad by a bonding method (e.g., a eutectic bonding method), and the pin 132 of the light emitting unit 130 may be electrically connected to the pad through a bonding material optionally, but not limited thereto. For instance, the light emitting device 100 may optionally include an insulating adhesive AL disposed between a light-emitting body 136 of the light emitting unit 130 (e.g., the light-emitting body 136 includes the semiconductor layer(s) and the light emitting layer(s)) and the conductive part 134 including the pad, such that the insulating adhesive AL may surround the bonding position where the pin 132 and the pad are bonded with each other for strengthening the bonding strength of the bonding position, but not limited thereto.

As shown in FIG. 1 and FIG. 2, the light emitting device 100 may include a color conversion structure 140 disposed between the circuit component layer 120 and the light emitting unit 130 (i.e., the color conversion structure 140 may be disposed between the transistor 122 and the light emitting unit 130), wherein the color conversion structure 140 is configured to filter, adjust and/or convert the color of the light passing through the color conversion structure 140 (i.e., the light of the light emitting unit 130), such that light with the required color or spectrum would be generated (i.e., the light having passed through the color conversion structure 140 is corresponding to the required color or spectrum of the sub-pixel SP). Namely, when the light of the light emitting unit 130 passes through the color conversion structure 140, the color conversion structure 140 filters, adjusts and/or converts the color of the light, and then, this light would pass through the substrate 110 and exit the light emitting device 100 from the bottom surface 110s of the substrate 110 (i.e., the light-emitting surface of the light emitting device 100). For instance, the color conversion structure 140 may include color filter, pigment, dye, a distributed Bragg reflector (DBR), fluorescence material, phosphorescence material, QD material, electrochromic material, other suitable color converting material or a combination thereof, thereby achieving the color converting effect. Note that the material of the color conversion structure 140 may be related to the color of light of the light emitting unit 130. For instance, if the light of the light emitting unit 130 is the blue light, the color conversion structure 140 may include QD material or other suitable color converting material, but not limited thereto.

As shown in FIG. 2, the color conversion structure 140 may include at least one sub-structure layer, wherein different sub-structure layers may include different types of the color converting materials. For instance, in FIG. 2, the color conversion structure 140 may include two sub-structure layers 140s1 and 140s2, the sub-structure layer 140s1 may include QD material and be disposed between the light emitting unit 130 and the sub-structure layer 140s2, and the sub-structure layer 140s2 may include color filter and be disposed between the sub-structure layer 140s1 and the circuit component layer 120 (i.e., the sub-structure layer 140s2 may be disposed between the sub-structure layer 140s1 and the transistor 122), but not limited thereto.

The sub-structure layer 140s1 includes a plurality of color conversion units 142, wherein the color conversion unit 142 includes the QD material, so as to convert the color of the light passing through the color conversion unit 142. For instance, the color conversion units 142 include a plurality of first color conversion units 142a and a plurality of second color conversion units 142b, wherein the first color conversion unit 142a is disposed in the sub-pixel SP1 to convert the light of the light emitting unit 130 (e.g., the blue light) into green light, and the second color conversion unit 142b is disposed in the sub-pixel SP2 to convert the light of the light emitting unit 130 (e.g., the blue light) into red light. In FIG. 2, the first color conversion unit 142a is overlapped with the first light emitting unit 130a in the direction Z, and the second color conversion unit 142b is overlapped with the second light emitting unit 130b in the direction Z.

The sub-structure layer 140s1 further includes a plurality of light scattering units 144 configured to scatter the lights of the light emitting units 130. In FIG. 2, a light scattering unit 144c in the light scattering units 144 is disposed in the sub-pixel SP3 to scatter the light of the third light emitting unit 130c. In FIG. 2, the light scattering unit 144c is overlapped with the third light emitting unit 130c in the direction Z. In the present disclosure, the light scattering unit 144 may include any suitable light scattering material(s). For instance, the light scattering material may include scattering particles, air particles, hollow material(s), hollow particles or a combination thereof, but not limited thereto.

Moreover, in FIG. 2, the sub-structure layer 140s1 further includes an insulating layer 146 configured to separate the color conversion units 142 and the light scattering units 144. Namely, a portion of the insulating layer 146 of the sub-structure layer 140s1 exists between two color conversion units 142, between two light scattering units 144 or between one color conversion unit 142 and one light scattering unit 144 in the horizontal direction (e.g., the direction X and/or the direction Y). In some embodiments, at least a portion of the insulating layer 146 may exist between two sub-pixels SP in the horizontal direction (e.g., the direction X and/or the direction Y). In the present disclosure, the insulating layer 146 may include the insulating materials. Optionally, the insulating layer 146 may include black light-absorbing material(s) (e.g., black resin, molybdenum aluminum alloy), black light-reflecting material(s), organic material(s), inorganic material(s), multi-layer with organic and inorganic materials, the light scattering material(s), air particles, hollow material(s), hollow particles or a combination thereof (e.g., a hybrid structure or composite materials), so as to make the light-emitting effect of the light emitting device 100 be enhanced (e.g., the scattering particles would reflect the light to achieve the light-converging effect), to improve or prevent the light color mixing or the light leakage from adjacent sub-pixel, or to be a blocking wall (e.g., a bank) in the manufacturing process (e.g., a blocking wall of an ink-jet printing (IJP) process or a blocking wall of a coating process of the photo resist), but not limited thereto.

In addition, the sub-structure layer 140s1 may further include at least one layer for protecting the color conversion unit 142 and the light scattering unit 144. In FIG. 2, the sub-structure layer 140s1 may include an insulating protection layer PL1 and an insulating protection layer PL2, wherein the color conversion unit 142 and the light scattering unit 144 may be disposed on the insulating protection layer PL1, a portion of the insulating protection layer PL1 may exist between the color conversion unit 142 and the insulating layer 146 in the horizontal direction (e.g., the direction X and/or the direction Y), a portion of the insulating protection layer PL1 may exist between the light scattering unit 144 and the insulating layer 146 in the horizontal direction (e.g., the direction X and/or the direction Y), a portion of the insulating protection layer PL1 may be disposed on the insulating layer 146, and the insulating protection layer PL2 may be disposed on the color conversion unit 142, the light scattering unit 144, the insulating layer 146 and the insulating protection layer PL1 and overlapped with the color conversion unit 142, the light scattering unit 144, the insulating layer 146 and the insulating protection layer PL1 in the direction Z. For instance, in FIG. 2, the color conversion unit 142 and the light scattering unit 144 may be disposed between the insulating protection layer PL1 and the insulating protection layer PL2 in the direction Z, and a portion of the insulating protection layer PL1 may surround the color conversion unit 142 and the light scattering unit 144 in the top view, but not limited thereto. For instance, in FIG. 2, the insulating protection layer PL2 may be directly in contact with the color conversion unit 142, the light scattering unit 144 and the insulating protection layer PL1, but not limited thereto. In the present disclosure, the insulating protection layer PL1 and the insulating protection layer PL2 may include insulating material(s) and/or water and oxygen blocking material(s) (e.g., silicon oxide (SiOₓ), silicon nitride (SiN_{y}), other suitable material or a combination thereof), but not limited thereto.

The sub-structure layer 140s2 includes at least one color filter 148 for filtering the color of the light passing through the color filter 148. For instance, in FIG. 2, the sub-structure layer 140s2 includes a first color filter 148a corresponding to the color (e.g., green) of the sub-pixel SP1, a second color filter 148b corresponding to the color (e.g., red) of the sub-pixel SP2 and a third color filter 148c corresponding to the color (e.g., blue) of the sub-pixel SP3, wherein the first color filter 148a is configured to improve the color purity of the green light of the sub-pixel SP1, to increase a full width at half maximum (FWHM) of the green spectrum or to filter non-green colors, the second color filter 148b is configured to improve the color purity of the red light of the sub-pixel SP2, to increase a FWHM of the red spectrum or to filter non-red colors, and the third color filter 148c is configured to improve the color purity of the blue light of the sub-pixel SP3, to increase a FWHM of the blue spectrum or to filter non-blue colors. In FIG. 2, a portion of the first color filter 148a is overlapped with the first light emitting unit 130a and the first color conversion unit 142a in the direction Z, a portion of the second color filter 148b is overlapped with the second light emitting unit 130b and the second color conversion unit 142b in the direction Z, and a portion of the third color filter 148c is overlapped with the third light emitting unit 130c and the light scattering unit 144c in the direction Z, so as to respectively form light path structures or light path light conversion structures of the sub-pixels SP. Moreover, optionally, in FIG. 2, the first color filter 148a, the second color filter 148b and the third color filter 148c may be partially overlapped with each other in the direction Z, and the position where the first color filter 148a, the second color filter 148b and the third color filter 148c are overlapped with each other may not be overlapped with the color conversion unit 142 and the light scattering unit 144 in the direction Z or may have a reduced overlapping area with the color conversion unit 142 and the light scattering unit 144 in the direction Z (e.g., the position where the first color filter 148a, the second color filter 148b and the third color filter 148c are overlapped with each other may be overlapped with the insulating layer 146 of the sub-structure layer 140s1 in the direction Z). Note that the stacking order of the first color filter 148a, the second color filter 148b and the third color filter 148c may be designed based on requirement(s) (the stacking order shown in FIG. 2 is an example).

In some embodiments, the color conversion structure 140 may further include other required structure(s). In FIG. 2, the color conversion structure 140 may further include an insulating layer 140i disposed between two sub-structure layers 140s1 and 140s2, so as to separate two sub-structure layers 140s1 and 140s2. For instance, the insulating layer 140i may serve as a flat layer, so as to make the sub-structure layer 140s1 have a flat bottom surface, but not limited thereto. For instance, the insulating layer 140i may have a low refractive index, but not limited thereto. For instance, the insulating layer 140i may include the insulating material(s), wherein the insulating layer 140i may include an organic insulating layer, an inorganic insulating layer, a DBR, a hollow particle layer, other suitable insulating layer or a combination thereof. In FIG. 2, a portion of the insulating protection layer PL1 of the sub-structure layer 140s1 may be disposed between the color conversion unit 142 and the insulating layer 140i.

The light emitting device 100 may further include an insulating layer IN1 disposed between the color conversion structure 140 and the light emitting unit 130, wherein the insulating layer IN1 may be disposed on the color conversion structure 140 and partially cover the color conversion structure 140 at least, and the conductive part 134 including the pad may be disposed on the insulating layer IN1. For instance, the insulating layer IN1 may include the insulating material(s), and the insulating layer IN1 may serve as a flat layer to provide a flat surface, but not limited thereto. In FIG. 2, the color conversion structure 140 may be a structure between the insulating layer IN1 and the circuit component layer 120, but not limited thereto.

In the present disclosure, the light emitting unit 130 may be electrically connected to the electronic component(s) in the circuit component layer 120 by a suitable design. In the present disclosure, as shown in FIG. 2, since the color conversion structure 140 and the insulating layer IN1 are disposed between the light emitting unit 130 and the circuit component layer 120, a conductive path between the light emitting unit 130 and the circuit component layer 120 passes through the color conversion structure 140 and the insulating layer IN1. In the present disclosure, the light emitting unit 130 may be electrically connected to the signal line 124 and the transistor 122 in the circuit component layer 120 (i.e., the first light emitting unit 130a may be electrically connected to the first transistor 122a, the second light emitting unit 130b may be electrically connected to the second transistor 122b, and the third light emitting unit 130c may be electrically connected to the third transistor 122c).

In detail, in FIG. 2, the color conversion structure 140 in each sub-pixel SP has a first portion 140p1, a second portion 140p2 and a third portion 140p3 (i.e., since the light emitting device 100 includes a plurality of sub-pixels SP, the color conversion structure 140 includes a plurality of first portions 140p1, a plurality of second portions 140p2 and a plurality of third portions 140p3), the first portion 140p1 is overlapped with the light emitting unit 130 in the direction Z, the second portion 140p2 and the third portion 140p3 are adjacent to the first portion 140p1 and not overlapped with the light emitting unit 130 in the direction Z. Note that the first portion 140p1, the second portion 140p2 and the third portion 140p3 of the color conversion structure 140 are stacked by different components and/or structures. As shown in FIG. 2, the first portion 140p1 is a region simultaneously having the color conversion unit 142 and the color filter 148 or simultaneously having the light scattering unit 144 and the color filter 148, and each of the second portion 140p2 and the third portion 140p3 may be a region adjacent to the first portion 140p1 and including the insulating layer 146 (in FIG. 2, if three color filters 148 overlapped with each other exist, the position where three color filters 148 overlapped with each other is in the second portion 140p2 and/or the third portion 140p3). In the present disclosure, the relative positions of the first portion 140p1, the second portion 140p2 and the third portion 140p3 in the top view may be designed based on requirement(s). For example (as shown in FIG. 1 and FIG. 2), in the top view, the second portion 140p2 and the third portion 140p3 are on the opposite sides of the first portion 140p1, such that the first portion 140p1 is between the second portion 140p2 and the third portion 140p3, but not limited thereto.

In each sub-pixel SP of the present disclosure, the electrode of the light emitting unit 130 including the pad of the conductive part 134_1 and the pin 132_1 may be electrically connected to the transistor 122 of the circuit component layer 120 through the second portion 140p2 (e.g., a conductive path in the second portion 140p2) of the color conversion structure 140 (i.e., the light emitting unit 130 may be electrically connected to the transistor 122 through a conductive component in the second portion 140p2), and the electrode of the light emitting unit 130 including the pad of the conductive part 134_2 and the pin 132_2 may be electrically connected to the signal line 124 of the circuit component layer 120 for receiving the reference signal through the third portion 140p3 (e.g., a conductive path in the third portion 140p3) of the color conversion structure 140 (i.e., the light emitting unit 130 may be electrically connected to the signal line 124 through a conductive component in the third portion 140p3). On the other hand, since the position where three color filters 148 overlapped with each other exists in the second portion 140p2 and/or the third portion 140p3, and the light emitting unit 130 may be electrically connected to the transistor 122 and the signal line 124 of the circuit component layer 120 through the second portion 140p2 (e.g., the conductive path of the second portion 140p2) and the third portion 140p3 (e.g., the conductive path of the third portion 140p3) of the color conversion structure 140 respectively, the electrode of the light emitting unit 130 may be electrically connected to the transistor 122 through the first color filter 148a, the second color filter 148b and the third color filter 148c in the second portion 140p2 (i.e., the electrode of the light emitting unit 130 may be electrically connected to the transistor 122 through the conductive path of the second portion 140p2 in a hole passing through three color filters 148), and the electrode of the light emitting unit 130 may be electrically connected to the signal line 124 through the first color filter 148a, the second color filter 148b and the third color filter 148c in the third portion 140p3 (i.e., the electrode of the light emitting unit 130 may be electrically connected to the signal line 124 through the conductive path of the third portion 140p3 in a hole passing through three color filters 148).

In FIG. 2, the conductive path in the second portion 140p2 of the color conversion structure 140 includes a conductive structure CS1. The conductive structure CS1 of the second portion 140p2 may include a plurality of conductive elements CM1, CM2 and CM3, wherein the conductive element CM1 may pass through the first color filter 148a, the second color filter 148b, the third color filter 148c and the insulating layer 140i, the conductive element CM2 may be disposed on the insulating layer 140i, and the conductive element CM3 may pass through the insulating protection layer PL1, the insulating protection layer PL2 and the insulating layer 146. Furthermore, the light emitting device 100 may further include a conductive part CCX1 passing though the insulating layer IN1 and disposed on the conductive structure CS1, and the circuit component layer 120 may include conductive parts 126C1 and 126C2 (the conductive parts 126C1 and 126C2 of the circuit component layer 120 are structures belonging to the conductive layers of the circuit component layer 120, wherein the conductive part 126C1 is disposed on the insulating layer 12013, and the conductive part 126C2 passes through the insulating layers 12013). Therefore, the electrode of the light emitting unit 130 including the pad of the conductive part 134_1 and the pin 132_1 may be electrically connected to the transistor 122 through the conductive part CCX1, the conductive structure CS1 in the second portion 140p2 including the conductive elements CM1, CM2 and CM3 and the conductive parts 126C1 and 126C2 of the circuit component layer 120. For instance, as shown in FIG. 2, one-to-one connection is used between the light emitting units 130 and the conductive structures CS1 of the second portions 140p2, such that the number of the light emitting units 130 is the same as the number of the conductive structures CS1 of the second portions 140p2, but not limited thereto.

In FIG. 2, the conductive path of the third portion 140p3 of the color conversion structure 140 includes a conductive structure CS2. The conductive structure CS2 of the third portion 140p3 may include a plurality of conductive elements CM4, CM5 and CM6, wherein the conductive element CM4 may pass through the first color filter 148a, the second color filter 148b, the third color filter 148c and the insulating layer 140i, the conductive element CM5 may be disposed on the insulating layer 140i, and the conductive element CM6 may pass through the insulating protection layer PL1, the insulating protection layer PL2 and the insulating layer 146. Furthermore, the light emitting device 100 may further include a conductive part CCX2 passing through the insulating layer IN1 and disposed on the conductive structure CS2, and the circuit component layer 120 may include conductive parts 126C3 and 126C4 (the conductive parts 126C3 and 126C4 of the circuit component layer 120 are structures belonging to the conductive layers of the circuit component layer 120, wherein the conductive part 126C3 is disposed on the insulating layer 12013, and the conductive part 126C4 passes through the insulating layers 120i1, 120i2 and 120i3). Therefore, the electrode of the light emitting unit 130 including the pad of the conductive part 134_2 and the pin 132_2 may be electrically connected to the signal line 124 through the conductive part CCX2, the conductive structure CS2 in the third portion 140p3 including the conductive elements CM4, CM5 and CM6 and the conductive parts 126C3 and 126C4 of the circuit component layer 120. For instance, as shown in FIG. 2, one-to-one connection is used between the light emitting units 130 and the conductive structures CS2 of the third portions 140p3, such that the number of the light emitting unit 130 is the same as the number of the conductive structures CS2 of the third portions 140p3, but not limited thereto.

Moreover, in the present disclosure, the conductive elements CM1, CM2, CM3, CM4, CM5 and CM6 and the conductive parts CCX1 and CCX2 may include the conductive materials. For instance, each of the conductive elements CM1, CM2, CM3, CM4, CM5, CM6 and the conductive parts CCX1 and CCX2 may include a structure with one conductive material and a composite structure with a plurality of conductive materials. For instance, the composite structure may be a composite element containing copper and silver, a composite element containing ITO and copper (e.g., this composite element is stacked by ITO, copper and ITO in sequence), a composite element containing ITO and silver (e.g., this composite element is stacked by ITO, silver and ITO in sequence), a composite element containing ITO, silver and magnesium (e.g., this composite element is stacked by ITO, silver and magnesium in sequence) or other suitable composite element, but not limited thereto.

In FIG. 2, the insulating layer 146 in the sub-structure layer 140s1 of the color conversion structure 140 may have an opening OP1 situated in the second portion 140p2 and an opening OP2 situated in the third portion 140p3, and the color conversion unit 142 or the light scattering unit 144 may be disposed between the opening OP1 and the opening OP2 in each sub-pixel SP, wherein the conductive element CM3 may pass through the insulating protection layer PL1, the insulating protection layer PL2 and the insulating layer 146 through the opening OP1 in the second portion 140p2, and the conductive element CM6 may pass through the insulating protection layer PL1, the insulating protection layer PL2 and the insulating layer 146 through the opening OP2 in the third portion 140p3. In FIG. 2, a width WC of the color conversion unit 142 and a width WS of the light scattering unit 144 may be greater than a width W1 of the opening OP1 in the second portion 140p2, and the width W1 of the opening OP1 in the second portion 140p2 may be greater than a width W2 of the opening OP2 in the third portion 140p3, but not limited thereto.

In some embodiments, the opening OP1 in the second portion 140p2 may serve as a storage tank of the QD material. Thus, in the forming process of the color conversion unit 142, overflowed, displaced, splashed, detached, contaminated and/or repaired QD material may be collected in the opening OP1 (i.e., the storage tank) in the second portion 140p2, so as to enhance the yield rate. Moreover, in FIG. 2, since the opening OP1 in the second portion 140p2 may serve as the storage tank of the QD material, the conductive element CM3 may be formed along the sidewall(s) of the opening OP1 in the second portion 140p2, and a portion of the insulating layer IN1 subsequently formed on the color conversion structure 140 may be disposed (filled) in the opening OP1 in the second portion 140p2.

In FIG. 2, the insulating layer IN1 disposed between the color conversion structure 140 and the light emitting unit 130 may have an opening OP3 and an opening OP4, wherein the opening OP3 may overlap the opening OP1 of the insulating layer 146 of the second portion 140p2 in the direction Z, the conductive part CCX1 may pass through the insulating layer IN1 and be electrically connected to the conductive structure CS1 of the second portion 140p2 through the opening OP3, the opening OP4 may overlap the opening OP2 of the insulating layer 146 of the third portion 140p3 in the direction Z, and the conductive part CCX2 may pass through the insulating layer IN1 and be electrically connected to the conductive structure CS2 of the third portion 140p3 through the opening OP4. In FIG. 2, a depth D1 of the opening OP1 of the insulating layer 146 in the second portion 140p2 may be greater than a depth D3 of the opening OP3 of the insulating layer IN1, and a depth D2 of the opening OP2 of the insulating layer 146 in the third portion 140p3 may be greater than a depth D4 of the opening OP4 of the insulating layer IN1.

Because of the existences of the conductive structure CS1 in the second portion 140p2, the conductive structure CS2 in the third portion 140p3 and the conductive parts CCX1 and CCX2, the light emitting unit 130 may be electrically connected to the electronic component of the circuit component layer 120 through a shorter electrical connection path (i.e., this electrical connection is achieved without connecting a component in a peripheral region), such that the resistance between the light emitting unit 130 and the electronic component of the circuit component layer 120 is reduced. Therefore, the signal loss is reduced, and an additional design (a structure and/or a forming process) configured to enhance the signal strength is omitted, thereby increasing the performance of the light emitting device 100 and reducing the cost of the light emitting device 100.

In addition, the light emitting device 100 may further include a reflective layer 150 disposed on the light emitting unit 130 (i.e., the light emitting unit 130 may be between the reflective layer 150 and the substrate 110), wherein the reflective layer 150 may be configured to reflect the light of the light emitting unit 130, such that the light intensity of the light generated by the light emitting unit 130 and passing through the substrate 110 is increased. In the present disclosure, the reflective layer 150 may include material(s) with high reflectivity. In some embodiments, the reflective layer 150 may include metal material(s) with high reflectivity. For instance, the material of the reflective layer 150 may include silver, aluminum, molybdenum, other suitable inorganic metal material(s), material(s) with high reflectivity, total reflection material(s), a micro lens array reflective layer or a combination thereof (e.g., alloys of the above metal materials), but not limited thereto. Moreover, in addition to high reflectivity and total reflectivity, the material of the reflective layer 150 may further have high conductivity, low impedance, pressure resistance, impact resistance and/or scratch resistance, but not limited thereto.

In the present disclosure, the light emitting device 100 may further include other required component(s) and/or structure(s). As shown in FIG. 2, the light emitting device 100 may optionally include an insulating layer IN2 disposed between the light emitting unit 130 and the reflective layer 150, wherein the insulating layer IN2 may cover and protect the light emitting unit 130. The insulating layer IN2 may include insulating material(s), insulating material(s) with high resistance, organic material(s) with high leveling property, organic material(s) with high filling property, resin material(s) or acrylic material(s) with high light transmittance, resin material(s) or acrylic material(s) with good heat dissipation, resin material(s) or acrylic material(s) with a low yellowing rate after irradiation, or a combination thereof, but not limited thereto.

As shown in FIG. 2, the light emitting device 100 may optionally include a pixel define layer 160 configured to separate the sub-pixels SP from each other and/or to separate the light emitting units 130 from each other, wherein the pixel define layer 160 may include the insulating material(s) to serve as an insulating layer. In FIG. 2, the pixel define layer 160 may be disposed between the reflective layer 150 and the color conversion structure 140, and be disposed between the reflective layer 150 and the insulating layer IN1. In the present disclosure, the pixel define layer 160 may be a single-layer structure or a multi-layer structure. For instance, in FIG. 2, the pixel define layer 160 may be a two-layer structure including two sub-layers 160a and 160b, and a portion of an insulating adhesive AL may exist between two sub-layers 160a and 160b of the pixel define layer 160, but not limited thereto.

In FIG. 2, the pixel define layer 160 may include a plurality of parts 162 (e.g., the first part 162a and the second part 162b), and at least a portion of the light emitting unit 130 may be disposed between two adjacent parts 162 of the pixel define layer 160 (e.g., at least a portion of the first light emitting unit 130a may be disposed between the first part 162a and the second part 162b). Note that “part 162” of the pixel define layer 160 is a partial region of the pixel define layer 160, and different parts 162 may be the same or similar.

The light emitting device of the present disclosure is not limited to the above embodiments. Further embodiments of the present disclosure are described below. For ease of comparison, same components will be labeled with the same symbol in the following. The following descriptions relate the differences between each of the embodiments, and repeated parts will not be redundantly described.

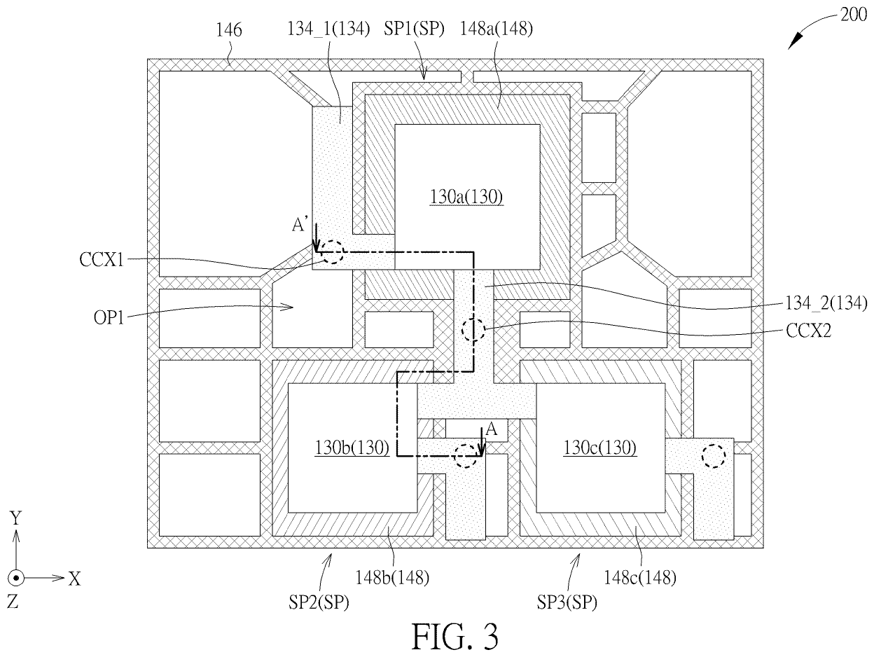

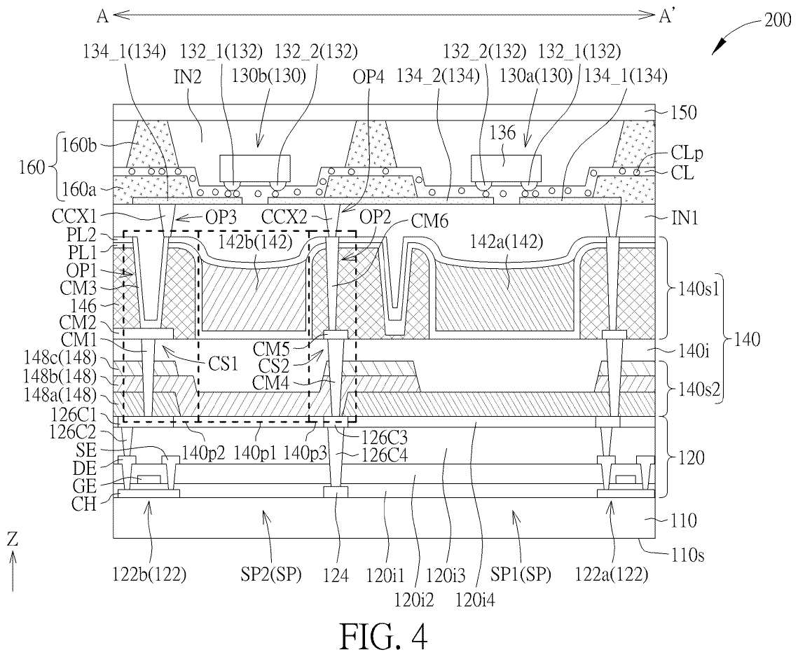

Referring to FIG. 3 and FIG. 4, FIG. 3 is a schematic diagram showing a top view of a light emitting device according to a second embodiment of the present disclosure, and FIG. 4 is a schematic diagram showing a cross-sectional view of a structure taken along a cross-sectional line A-A′ in FIG. 3. As shown in FIG. 3 and FIG. 4, a difference between this embodiment and the first embodiment is the design of the conductive path of the light emitting device 200 of this embodiment. In FIG. 3 and FIG. 4, the electrodes (this electrode includes the pad in the conductive part 134_2 and the pin 132_2) of the light emitting units 130 in different sub-pixels SP may be electrically connected to one signal line 124 through one conductive path. In FIG. 3 and FIG. 4, the pins 132_2 of the light emitting units 130 in different sub-pixels SP may be electrically connected to each other through the conductive part 134_2 including the pads, and these pins 132_2 may be electrically connected to one signal line 124 through the conductive part CCX2, the conductive structure CS2 in the third portion 140p3 including the conductive elements CM4, CM5 and CM6, and the conductive parts 126C3 and 126C4 in the circuit component layer 120, such that the electrodes (this electrode includes the pad in the conductive part 134_2 and the pin 132_2) of different light emitting units 130 may receive the reference signal through the conductive part CCX2, the conductive structure CS2 in the third portion 140p3 including the conductive elements CM4, CM5 and CM6, and the conductive parts 126C3 and 126C4 in the circuit component layer 120. Since one conductive structure CS2 in the third portion 140p3 is electrically connected to a plurality of light emitting units 130 in different sub-pixels SP, a total number of the light emitting units 130 in different the sub-pixels SP is greater than a total number of the third portions 140p3 (a total number of the conductive structures CS2 in the third portions 140p3). A total number of the pins 132_2 of the light emitting units 130 in different sub-pixels SP is greater than the total number of the third portions 140p3 and the total number of the conductive structures CS2 in the third portions 140p3.

For instance, in FIG. 3 and FIG. 4, the electrodes (this electrode includes the pad of the conductive part 134_2 and the pin 132_2) of the light emitting units 130 in different color sub-pixels SP (e.g., the first light emitting unit 130a, the second light emitting unit 130b and the third light emitting unit 130c) may be electrically connected to the signal line 124 through one conductive path (i.e., the conductive part CCX2, the conductive structure CS2 in the third portion 140p3 including the conductive elements CM4, CM5 and CM6 and the conductive parts 126C3 and 126C4 in the circuit component layer 120), but not limited thereto.

For example (not shown in figures), the electrodes (this electrode includes the pad of the conductive part 134_2 and the pin 132_2) of the light emitting units 130 in the same color sub-pixels SP (e.g., a plurality of first light emitting units 130a) may be electrically connected to the signal line 124 through one conductive path (i.e., the conductive part CCX2, the conductive structure CS2 in the third portion 140p3 including the conductive elements CM4, CM5 and CM6 and the conductive parts 126C3 and 126C4 in the circuit component layer 120), but not limited thereto. Since one conductive structure CS2 of one third portion 140p3 is electrically connected to a plurality of first light emitting units 130a, a total number of the first light emitting units 130a is greater than a total number of the third portions 140p3 (a total number of the conductive structures CS2 of the third portions 140p3).

In addition, the pin 132 of the light emitting unit 130 of this embodiment may be electrically connected to the pad of the conductive part 134 through another manner. For instance, in FIG. 4, the pin 132 of the light emitting unit 130 may be electrically connected to the pad of the conductive part 134 through a conductive film CL (e.g., ACF), wherein conductive particles CLp of the conductive film CL may exist between the pin 132 of the light emitting unit 130 and the pad of the conductive part 134 to make them be electrically connected to each other, but not limited thereto.

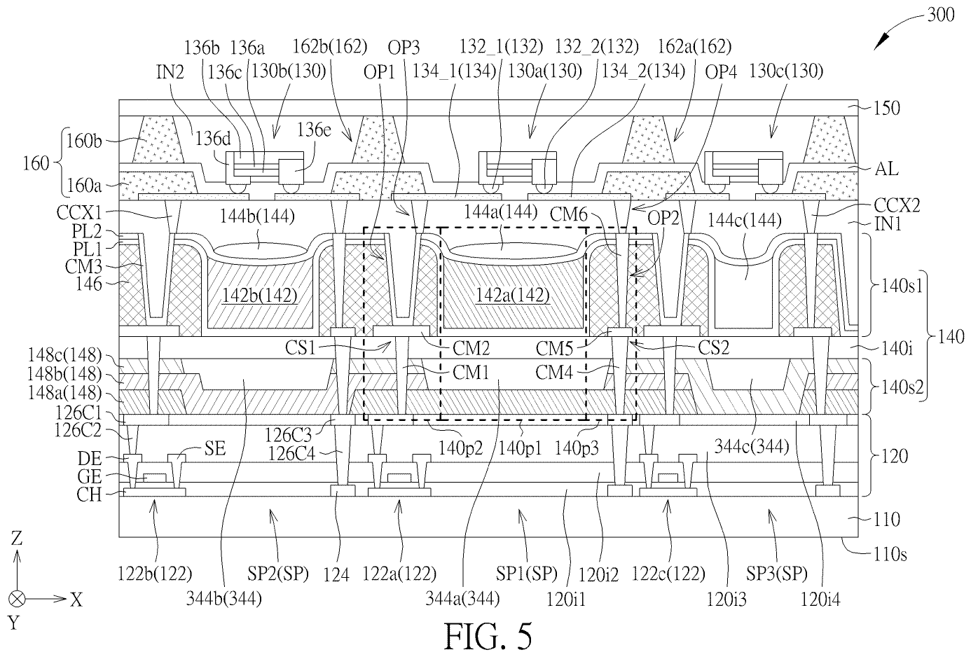

Referring to FIG. 5, FIG. 5 is a schematic diagram showing a cross-sectional view of a light emitting device according to a third embodiment of the present disclosure. As shown in FIG. 5, a difference between this embodiment and the first embodiment is the design of the optical film(s) of the light emitting device 300 of this embodiment. In FIG. 5, in the light scattering unit 144 of the sub-structure layer 140s1 of the color conversion structure 140, the light scattering unit 144 may further have a light scattering unit 144a disposed in the sub-pixel SP1 and scattering the light of the first light emitting unit 130a and a light scattering unit 144b disposed in the sub-pixel SP2 and scattering the light of the second light emitting unit 130b. For instance, the light scattering unit 144a in the sub-pixel SP1 and the light scattering unit 144b in the sub-pixel SP2 may be disposed between the insulating protection layer PL2 and the insulating layer IN1, and the light scattering unit 144c in the sub-pixel SP3 may be disposed between the insulating protection layer PL1 and the insulating protection layer PL2, but not limited thereto. For instance, the light scattering unit 144a disposed in the color conversion structure 140 may be corresponding to the first portion 140p1 of the sub-pixel SP1 and overlapped with the first light emitting unit 130a and the first color conversion unit 142a in the direction Z, and the light scattering unit 144b disposed in the color conversion structure 140 may be corresponding to the first portion 140p1 of the sub-pixel SP2 and overlapped with the second light emitting unit 130b and the second color conversion unit 142b in the direction Z.

In addition, the color conversion structure 140 may optionally include a scattering layer 344 disposed between the insulating layer 140i and the color filter 148 and configured to scatter the light of the light emitting unit 130, thereby increasing an angle range of the light emitting from the light emitting device 300. In FIG. 5, a scattering part 344a of the scattering layer 344 is disposed in the sub-pixel SP1 and corresponding to (overlapped with) the first light emitting unit 130a, the first color conversion unit 142a and the first color filter 148a in the direction Z (i.e., the scattering part 344a is disposed in the color conversion structure 140 and corresponding to the first portion 140p1 of the sub-pixel SP1), a scattering part 344b of the scattering layer 344 is disposed in the sub-pixel SP2 and corresponding to (overlapped with) the second light emitting unit 130b, the second color conversion unit 142b and the second color filter 148b in the direction Z (i.e., the scattering part 344b is disposed in the color conversion structure 140 and corresponding to the first portion 140p1 of the sub-pixel SP2), and a scattering part 344c of the scattering layer 344 is disposed in the sub-pixel SP3 and corresponding to (overlapped with) the third light emitting unit 130c, the light scattering unit 144c and the third color filter 148c in the direction Z (i.e., the scattering part 344c is disposed in the color conversion structure 140 and corresponding to the first portion 140p1 of the sub-pixel SP3). In this embodiment, the scattering layer 344 may include any suitable light scattering material(s). For instance, the scattering layer 344 may include scattering particles and aforementioned suitable scattering material(s), but not limited thereto.

Moreover, in the light emitting unit 130 (e.g., a lateral micro LED) shown in FIG. 5, a light emitting layer 136c is disposed between two semiconductor layers 136a and 136b in the direction Z, the semiconductor layer 136a is disposed between the pin 132 and the semiconductor layer 136b in the direction Z, a connecting element 136d containing the conductive material(s) is electrically connected between the semiconductor layer 136a and the pin 132_1 (an insulating material exists between the connecting element 136d and the semiconductor layer 136b to separate them from each other), and a connecting element 136e containing the conductive material(s) is electrically connected between the semiconductor layer 136b and the pin 132_2 (an insulating material exists between the connecting element 136e and the semiconductor layer 136a to separate them from each other). For instance, the semiconductor layer 136a may be a P-type semiconductor layer, the semiconductor layer 136b may be a N-type semiconductor layer, and the light emitting layer 136c may be a multiple quantum well (MQW), but not limited thereto.

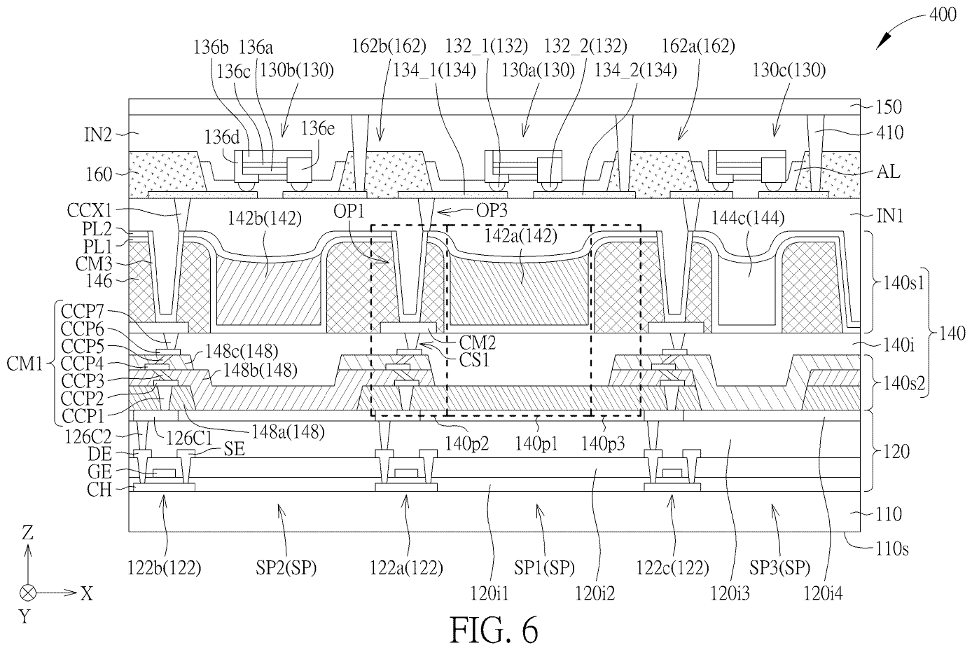

Referring to FIG. 6, FIG. 6 is a schematic diagram showing a cross-sectional view of a light emitting device according to a fourth embodiment of the present disclosure. As shown in FIG. 6, a difference between this embodiment and the first embodiment is the design of the conductive path of the light emitting device 400 of this embodiment. In this embodiment, the reflective layer 150 may have a conductivity and be configured to transmit the reference signal, wherein the light emitting unit 130 may be electrically connected to the reflective layer 150, such that the light emitting unit 130 may receive the reference signal through the reflective layer 150. Since the light emitting unit 130 is disposed between the reflective layer 150 and the color conversion structure 140, the conductive path configured to transmit the reference signal and electrically connected to the light emitting unit 130 does not need to pass through the color conversion structure 140.

The conductive path existing between the light emitting unit 130 and the reflective layer 150 may be designed based on requirement(s). In some embodiments, the light emitting unit 130 may be electrically connected to the reflective layer 150 through one part 162 of the pixel define layer 160 (i.e., the electrode of the light emitting unit 130 may be electrically connected to the reflective layer 150 through a hole passing through one part 162 of the pixel define layer 160 or through a portion crawling on a surface of one part 162 of the pixel define layer 160).

For example (as shown in FIG. 6), the conductive path between the light emitting unit 130 and the reflective layer 150 may include a conductive part 410, wherein the conductive part 410 may pass through the insulating layer IN2 and one part 162 of the pixel define layer 160, so as to be electrically connected between the reflective layer 150 and the light emitting unit 130 (i.e., to be electrically connected between the reflective layer 150 and the conductive part 134_2 including the pad). In the sub-pixel SP1 shown in FIG. 6, the conductive part 410 may pass through the insulating layer IN2 and the first part 162a of the pixel define layer 160, so as to be electrically connected between the reflective layer 150 and the first light emitting unit 130a (i.e., the first light emitting unit 130a may be electrically connected to the reflective layer 150 through the first part 162a of the pixel define layer 160). The pixel define layer 160 shown in FIG. 6 may be a single-layer structure, and a portion of the insulating layer IN2 may be disposed on the pixel define layer 160.

In addition, the conductive element CM1 of the conductive structure CS1 in the second portion 140p2 of the color conversion structure 140 may include a plurality of conductive sub-parts CCP1, CCP2, CCP3, CCP4, CCP5, CCP6 and CCP7. For example (as shown in FIG. 6), the conductive sub-parts CCP2, CCP4 and CCP6 may be misaligned with each other in the cross-sectional view, the conductive sub-part CCP1 may pass through the first color filter 148a and be connected between the conductive sub-part CCP2 and the conductive part 126C1 in the circuit component layer 120, the conductive sub-part CCP3 may (obliquely) pass through the second color filter 148b and be connected between the conductive sub-part CCP2 and the conductive sub-part CCP4, the conductive sub-part CCP5 may (obliquely) pass through the third color filter 148c and be connected between the conductive sub-part CCP4 and the conductive sub-part CCP6, and the conductive sub-part CCP7 may pass through the insulating layer 140i and be connected between the conductive sub-part CCP6 and the conductive element CM2, but not limited thereto.

Moreover, the design of the light emitting unit 130 shown in FIG. 6 may be the same as the light emitting unit 130 shown in FIG. 5. Therefore, this part will not be redundantly described.

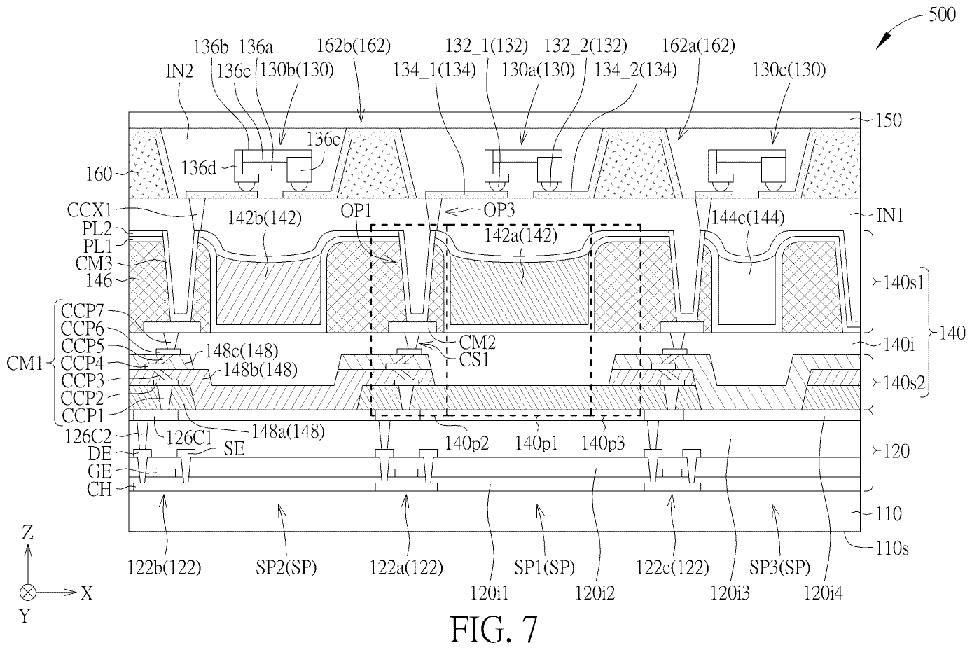

Referring to FIG. 7, FIG. 7 is a schematic diagram showing a cross-sectional view of a light emitting device according to a fifth embodiment of the present disclosure. As shown in FIG. 7, a difference between this embodiment and the fourth embodiment is the design of the conductive path between the light emitting unit 130 and the reflective layer 150 of the light emitting device 500 of this embodiment. As shown in FIG. 7, the conductive path between the light emitting unit 130 and the reflective layer 150 may be realized by extending the conductive part 134_2 including the pad. In FIG. 7, the conductive part 134_2 may extend and crawl on one part 162 of the pixel define layer 160, such that a portion of the conductive part 134_2 may be between the reflective layer 150 and the pixel define layer 160 to be electrically connected between the light emitting unit 130 and the reflective layer 150. In the sub-pixel SP1 shown in FIG. 7, the conductive part 134_2 may crawl on the first part 162a of the pixel define layer 160 to be electrically connected between the reflective layer 150 and the first light emitting unit 130a (i.e., the first light emitting unit 130a may be electrically connected to the reflective layer 150 through the first part 162a of the pixel define layer 160). For instance, the conductive part 134_2 may be directly in contact with the reflective layer 150, but not limited thereto.

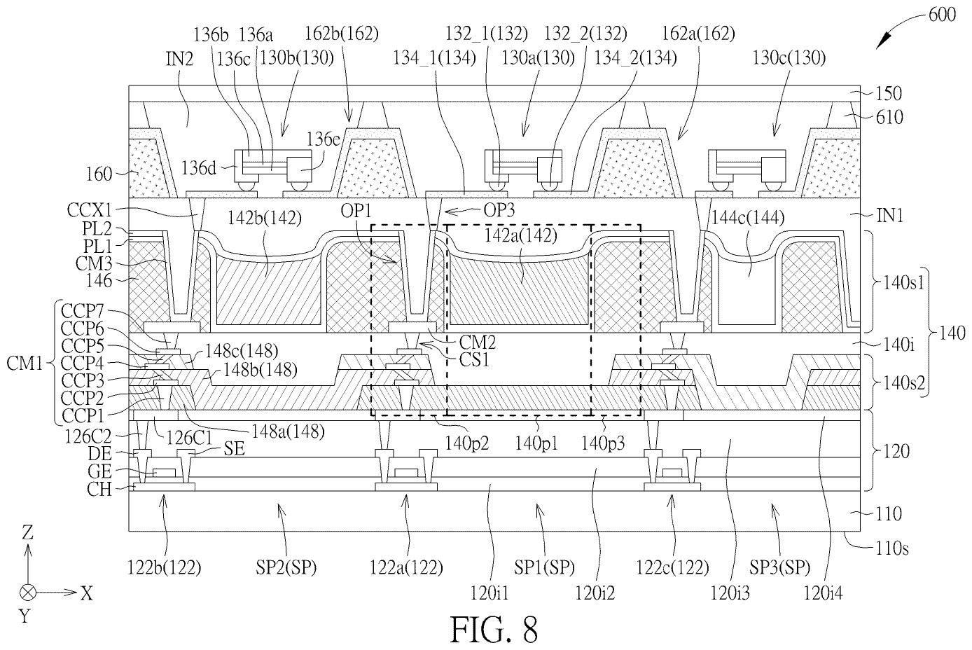

Referring to FIG. 8, FIG. 8 is a schematic diagram showing a cross-sectional view of a light emitting device according to a sixth embodiment of the present disclosure. As shown in FIG. 8, a difference between this embodiment and the fifth embodiment is the design of the conductive path between the light emitting unit 130 and the reflective layer 150 of the light emitting device 600 of this embodiment. As shown in FIG. 8, the conductive path between the light emitting unit 130 and the reflective layer 150 may further include a conductive part 610 disposed on the pixel define layer 160 and the conductive part 134_2 and electrically connected between the conductive part 134_2 and the reflective layer 150, such that the light emitting unit 130 may receive the reference signal through the conductive part 134_2, the conductive part 610 and the reflective layer 150. For example (as shown in FIG. 8), the conductive part 610 may be directly in contact with the reflective layer 150, but not limited thereto. In another embodiment, the conductive part 610 may be connected to the reflective layer 150 through other conductive structure(s), but not limited thereto. Moreover, the shape of the conductive part 610 may be designed based on requirement(s). For instance, in cross-sectional view, a width of a top of the conductive part 610 may be less than or greater than a width of a bottom of the conductive part 610, or the conductive part 610 may a structure having a curved edge (e.g., an arc edge), but not limited thereto.

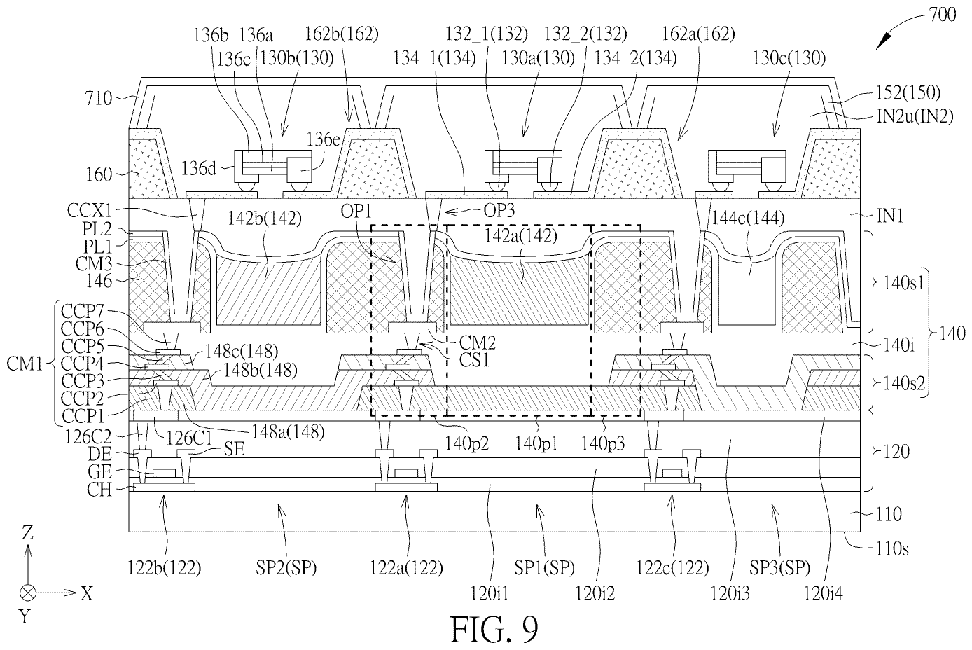

Referring to FIG. 9, FIG. 9 is a schematic diagram showing a cross-sectional view of a light emitting device according to a seventh embodiment of the present disclosure. As shown in FIG. 9, a difference between this embodiment and the fifth embodiment is that the reflective layer 150 of the light emitting device 700 of this embodiment is a patterning layer, such that the reflective layer 150 has a plurality of reflecting units 152 connected between different conductive parts 134_2. Also, the insulating layer IN2 may be a patterning layer and have a plurality of insulating units IN2u overlapping (covering) the light emitting units 130 in the direction Z. The insulating unit IN2u may have a suitable shape and suitable edges, so as to make the reflecting unit 152 disposed on the insulating unit IN2u be capable of having a suitable shape to suitably reflect the light of the light emitting unit 130, wherein the insulating units IN2u may be connected to or separated from each other. For instance, in FIG. 9, the insulating unit IN2u may make the reflecting unit 152 have a U-shape, and the insulating units IN2u may be separated from each other, but not limited thereto. If the reflective layer 150 (the reflecting unit 152) has the conductivity, the light emitting units 130 may be electrically connected to each other through the reflective layer 150 (the reflecting unit 152); if the reflective layer 150 (the reflecting unit 152) does not have the conductivity, the light emitting units 130 may be independent of each other.

Optionally, the light emitting device 700 may further include an insulating layer 710 disposed on the reflective layer 150, wherein a portion of the insulating layer 710 may be filled into a recess between two reflecting units 152. For example (as shown in FIG. 9), the insulating layer 710 may cover the reflective layer 150 (the reflecting unit 152), such that a top surface of the insulating layer 710 is higher than the reflective layer 150 (the reflecting unit 152), but not limited thereto. For example (not shown in figures), the insulating layer 710 may be filled into the recess between two reflecting units 152 for flatting, such that the reflecting units 152 and the insulating layer 710 may together provide a common flatting surface, but not limited thereto.

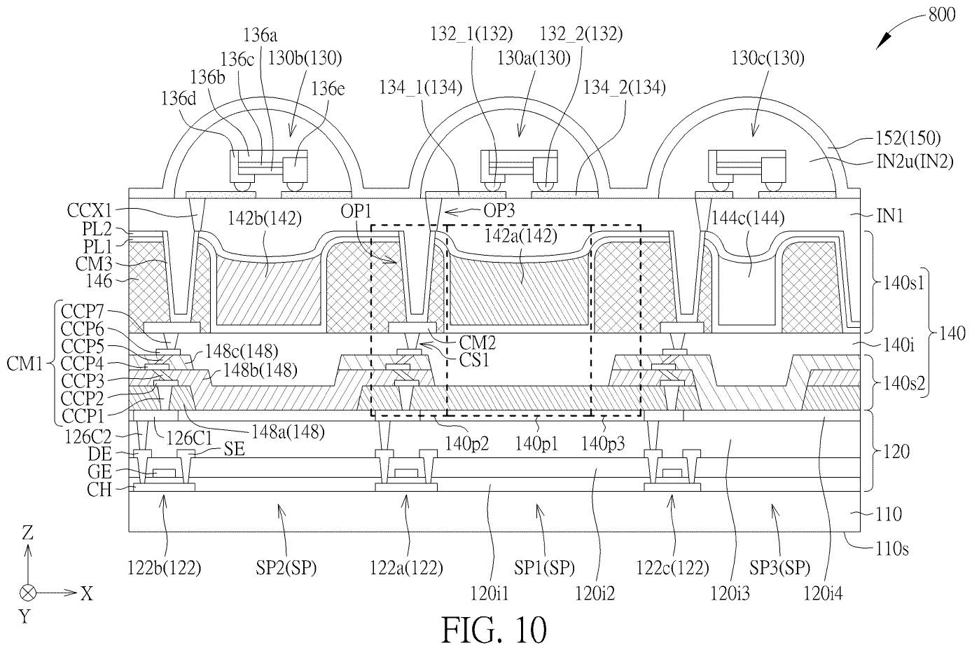

Referring to FIG. 10, FIG. 10 is a schematic diagram showing a cross-sectional view of a light emitting device according to an eighth embodiment of the present disclosure. As shown in FIG. 10, a difference between this embodiment and the fifth embodiment is the design of the conductive path between the light emitting unit 130 and the reflective layer 150 of the light emitting device 800 of this embodiment. In FIG. 10, the light emitting device 800 may not have the pixel define layer 160, and the conductive part 134_2 may extend on the insulating layer IN1 and be connected to the reflective layer 150. Also, in order to make the reflective layer 150 be capable of being connected to the conductive part 134_2, the insulating layer IN2 may be a patterning layer and have a plurality of insulating units IN2u overlapping (covering) the light emitting units 130 in the direction Z, and the conductive part 134_2 may extend to or extend out of the boundary of the insulating unit IN2u to be connected to the reflective layer 150. For instance, the insulating unit IN2u may have a curved edge (e.g., a semicircle arc) to make the reflective layer 150 have a curved (e.g., semicircular) reflecting unit 152 overlapping the insulating unit IN2u, but not limited thereto.

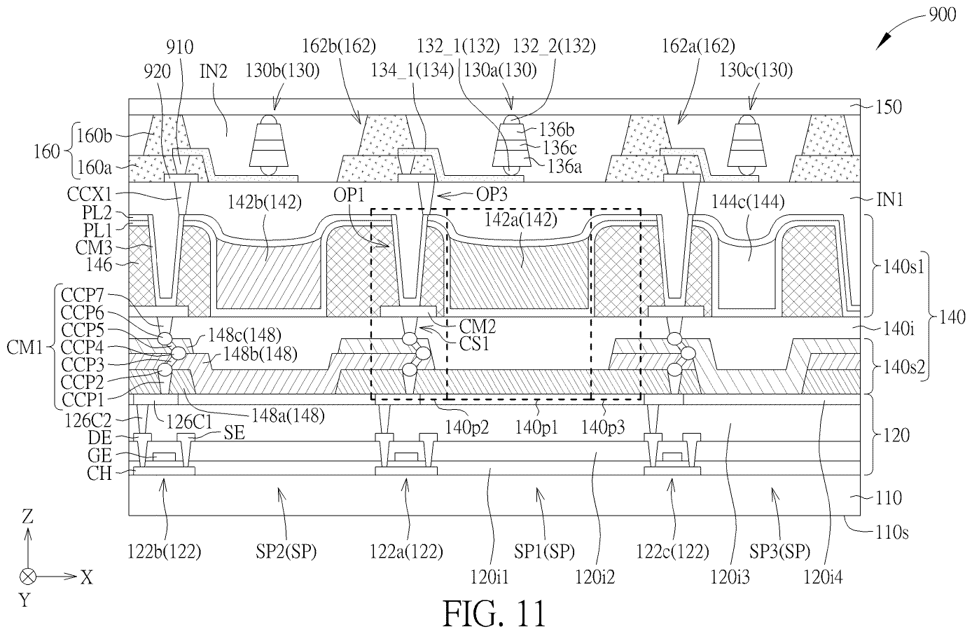

Referring to FIG. 11, FIG. 11 is a schematic diagram showing a cross-sectional view of a light emitting device according to a ninth embodiment of the present disclosure. As shown in FIG. 11, a difference between this embodiment and the first embodiment is the type of the light emitting unit 130 of the light emitting device 900 of this embodiment. In FIG. 11, the light emitting unit 130 may be a vertical LED, wherein a light emitting layer 136c may be disposed between two semiconductor layers 136a and 136b in the direction Z, the semiconductor layer 136a may be disposed between the light emitting layer 136c and the pin 132_1 in the direction Z, the semiconductor layer 136b may be disposed between the light emitting layer 136c and the pin 132_2 in the direction z (i.e., two semiconductor layers 136a and 136b and the light emitting layer 136c may be disposed between two pins 132_1 and 132_2 in the direction Z), the pin 132_1 may be disposed between the conductive part 134_1 and the semiconductor layer 136a, and the pin 132_2 may be disposed between the semiconductor layer 136b and the reflective layer 150.

Moreover, in FIG. 11, the reflective layer 150 may have the conductivity and be configured to transmit the reference signal, and the light emitting unit 130 may be electrically connected to the reflective layer 150, such that the light emitting unit 130 may receive the reference signal through the reflective layer 150. Thus, the light emitting unit 130 may receive the reference signal by making the pin 132_2 (the electrode) be electrically connected to the reflective layer 150. For instance, in FIG. 11, the pin 132_2 may be directly in contact with the reflective layer 150, but not limited thereto.

In FIG. 11, the conductive part 134_1 may extend for being on the sub-layer 160a of the pixel define layer 160, and the conductive part 134_1 may be electrically connected to the conductive structure CS1 in the second portion 140p2 of the color conversion structure 140 through a conductive part 910 passing through the sub-layer 160a, a conductive part 920 disposed on the insulating layer IN1 and the conductive part CCX1 passing through the insulating layer IN1, thereby being electrically connected to the transistor 122 in the circuit component layer 120.

Moreover, the conductive element CM1 of the conductive structure CS1 in the second portion 140p2 of the color conversion structure 140 may include a plurality of conductive sub-parts CCP1, CCP2, CCP3, CCP4, CCP5, CCP6 and CCP7. For example (as shown in FIG. 11), the spherical conductive sub-parts CCP2, CCP4 and CCP6 may be misaligned with each other in the cross-sectional view, the conductive sub-part CCP1 may pass through the first color filter 148a and be connected between the conductive sub-part CCP2 and the conductive part 126C1 in the circuit component layer 120, the conductive sub-part CCP3 may (obliquely) pass through the second color filter 148b and be connected between the conductive sub-part CCP2 and the conductive sub-part CCP4, the conductive sub-part CCP5 may (obliquely) pass through the third color filter 148c and be connected between the conductive sub-part CCP4 and the conductive sub-part CCP6, and the conductive sub-part CCP7 may pass through the insulating layer 140i and be connected between the conductive sub-part CCP6 and the conductive element CM2, but not limited thereto.

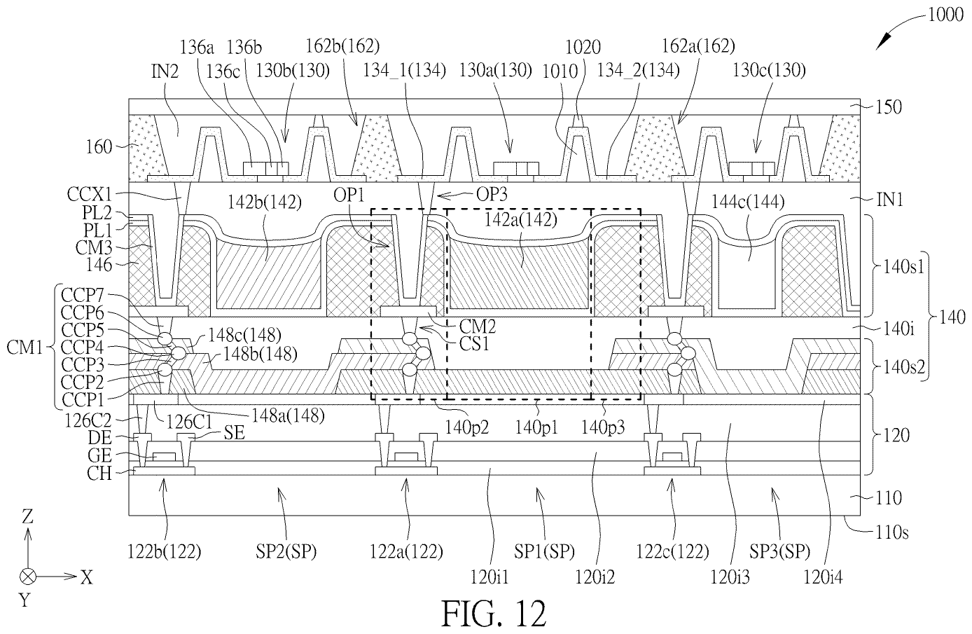

Referring to FIG. 12, FIG. 12 is a schematic diagram showing a cross-sectional view of a light emitting device according to a tenth embodiment of the present disclosure. As shown in FIG. 12, a difference between this embodiment and the ninth embodiment is the type of the light emitting unit 130 of the light emitting device 1000 of this embodiment. In FIG. 12, the light emitting unit 130 may be a Nano-rod LED, wherein the light emitting layer 136c may be disposed between two semiconductor layers 136a and 136b in the horizontal direction, the semiconductor layer 136a may be disposed on the pad of the conductive part 134_1 in the direction Z, and the semiconductor layer 136b may be disposed on the pad of the conductive part 134_2 in the direction Z.

In FIG. 12, the light emitting device 1000 may further include an insulating protruding structure 1010 disposed on the insulating layer IN1, and the conductive part 134 may extend for crawling on the insulating protruding structure 1010. In FIG. 12, the light emitting device 1000 may further a conductive part 1020 disposed on the insulating protruding structure 1010 and the conductive part 134_2, wherein the conductive part 1020 may be electrically connected between the conductive part 134_2 and the reflective layer 150. Therefore, in FIG. 12, the light emitting unit 130 may be electrically connected to the reflective layer 150 through the conductive part 134_2 and the conductive part 1020 (the insulating protruding structure 1010 may be configured to reduce a distance between a portion of the conductive part 134_2 and the reflective layer 150), and the light emitting unit 130 may be electrically connected to the transistor 122 in the circuit component layer 120 through the conductive part 134_1, the conductive part CCX1 and the conductive structure CS1 in the second portion 140p2 of the color conversion structure 140.

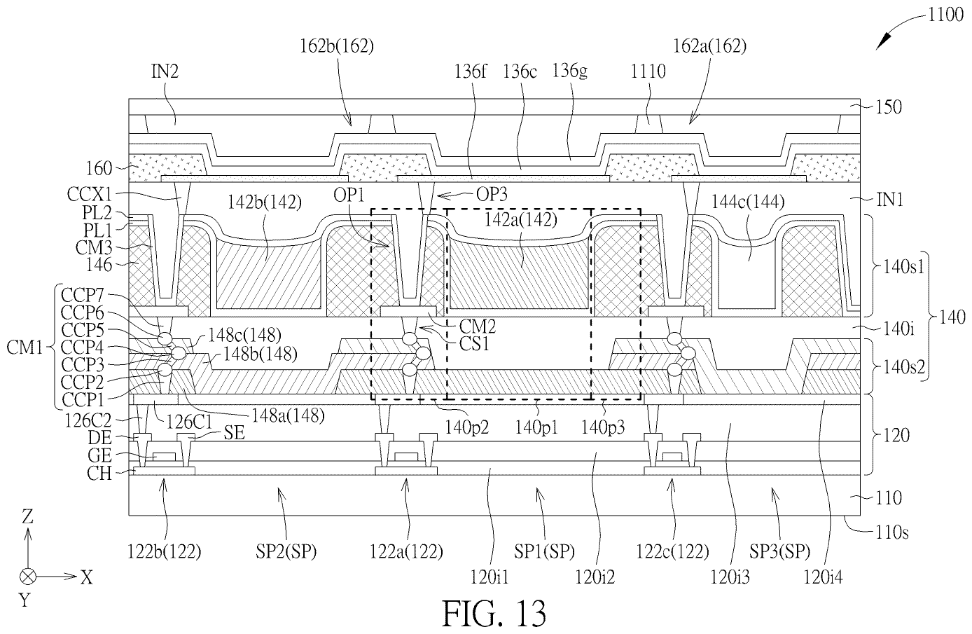

Referring to FIG. 13, FIG. 13 is a schematic diagram showing a cross-sectional view of a light emitting device according to an eleventh embodiment of the present disclosure. As shown in FIG. 13, a difference between this embodiment and the ninth embodiment the type of the light emitting unit 130 of the light emitting device 1100 of this embodiment. In FIG. 13, the light emitting unit 130 may be an OLED or a quantum dot LED, wherein the light emitting unit 130 may include two electrodes 136f and 136g (e.g., an anode and a cathode) and a light emitting layer 136c disposed between two electrodes 136f and 136g. In FIG. 13, the electrode 136f of the light emitting unit 130 may be electrically connected to the transistor 122 in the circuit component layer 120 through the conductive part CCX1 and the conductive structure CS1 in the second portion 140p2 of the color conversion structure 140, and the electrode 136g of the light emitting unit 130 may be electrically connected to the reflective layer 150 through a conductive part 1110 between the electrode 136g and the reflective layer 150 for receiving the reference signal. In FIG. 13, a portion of the electrode 136g, a portion of the light emitting layer 136c and the conductive part 1110 may be disposed on the pixel define layer 160.

In summary, in the present disclosure, because of the existence of the conductive path connected between the light emitting unit and the electronic component in the circuit component layer, the light emitting unit could be electrically connected to the electronic component in the circuit component layer through a shorter electrical connection path, such that the resistance between the light emitting unit and the electronic component in the circuit component layer is reduced. Therefore, the signal loss is reduced, and an additional design configured to enhance the signal strength is omitted, thereby increasing the performance of the light emitting device and reducing the cost of the light emitting device.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A light emitting device, comprising:
a substrate;
a first transistor and a first light emitting unit disposed on the substrate; and
a color conversion structure disposed between the first transistor and the first light emitting unit and having a first portion overlapped with the first light emitting unit and a second portion adjacent to the first portion;
wherein a light of the first light emitting unit passes through the first portion and the substrate, and the first light emitting unit is electrically connected to the first transistor through the second portion.

2. The light emitting device of claim 1, wherein the second portion has a conductive element, and the first light emitting unit is electrically connected to the first transistor through the conductive element.

3. The light emitting device of claim 1, wherein the color conversion structure has a first color conversion unit and a first color filter disposed between the first color conversion unit and the first transistor, and the first light emitting unit is electrically connected to the first transistor through the first color filter of the second portion.

4. The light emitting device of claim 3, wherein the color conversion structure has a second color filter partially overlapped with the first color filter, wherein the first light emitting unit is electrically connected to the first transistor through the second color filter of the second portion, and the first color filter is different from the second color filter in color.

5. The light emitting device of claim 1, wherein the color conversion structure has a third portion adjacent to the first portion, the first light emitting unit has a first electrode and a second electrode, the first electrode is electrically connected to the first transistor through the second portion, and the second electrode receives a reference signal through the third portion.

6. The light emitting device of claim 5, wherein the second portion and the third portion are disposed on opposite sides of the first light emitting unit.

7. The light emitting device of claim 6, further comprising a second transistor and a second light emitting unit having a third electrode and a fourth electrode, wherein the third electrode is electrically connected to the second transistor, and the fourth electrode receives the reference signal through the third portion.

8. The light emitting device of claim 7, further comprising a plurality of the first light emitting units, wherein the color conversion structure has a plurality of third portions configured to transmit the reference signal, and a number of the first light emitting units is greater than a number of the plurality of third portions.

9. The light emitting device of claim 1, wherein the color conversion structure has a first insulating layer and a first color conversion unit, and a portion of the first insulating layer surrounds the first color conversion unit in the first portion.

10. The light emitting device of claim 9, wherein the first light emitting unit is electrically connected to the first transistor by penetrating the first insulating layer.

11. The light emitting device of claim 10, wherein the color conversion structure has a second insulating layer disposed on the first insulating layer, and the second insulating layer directly contacts the first insulating layer and the first color conversion unit.

12. The light emitting device of claim 11, wherein the first light emitting unit is electrically connected to the first transistor by penetrating the second insulating layer.

13. The light emitting device of claim 1, further comprising a reflective layer disposed on the first light emitting unit and configured to reflect the light of the first light emitting unit.

14. The light emitting device of claim 13, further comprising a first insulating layer disposed between the reflective layer and the color conversion structure, wherein in a cross section, the first insulating layer has a first part and a second part, at least portion of the first light emitting unit is disposed between the first part and the second part, and the first light emitting unit is electrically connected to the reflective layer through the first part.

15. The light emitting device of claim 14, wherein the first light emitting unit receives a reference signal through the reflective layer.

16. The light emitting device of claim 1, wherein the color conversion structure has a first color conversion unit and a first insulating layer, the first insulating layer has a first opening and a second opening, the first color conversion unit is disposed between the first opening and the second opening, a width of the first color conversion unit is greater than a width of the second opening, and the width of the second opening is greater than a width of the first opening.

17. The light emitting device of claim 16, further comprising a second insulating layer disposed on the color conversion structure, wherein a portion of the second insulating layer is disposed in the second opening.

18. The light emitting device of claim 17, wherein the second insulating layer has a third opening overlapped with the second opening, and a depth of the second opening is greater than a depth of the third opening.
